(19) United States
(12) Patent Application Publication
(10) Pub. No.: US 2026/0136649 A1
(43) Pub. Date: May 14, 2026

(54) SEMICONDUCTOR DEVICE

(71) Applicant: FUJI ELECTRIC CO., LTD., Kawasaki-shi (JP)

(72) Inventor: Masaharu YAMAJI, Matsumoto-city (JP)

(73) Assignee: FUJI ELECTRIC CO., LTD., Kawasaki-shi (JP)

(21) Appl. No.: 19/345,440

(22) Filed: Sep. 30, 2025

(30) Foreign Application Priority Data
Nov. 14, 2024 (JP) 2024-198916

(51) Int. Cl. H10D 84/80; H10D 84/87

(52) U.S. Cl. CPC H10D 84/817; H10D 84/87

(57) ABSTRACT

A semiconductor device includes: a semiconductor substrate; a first semiconductor region provided in the semiconductor substrate; a second semiconductor region provided in the semiconductor substrate; a first electrode electrically connected to the first semiconductor region; a second electrode electrically connected to the second semiconductor region; an insulating film provided on a top surface side of the semiconductor substrate; and a resistive element provided on a top surfaces side of the insulating film, having a structure in which one end is electrically connected to the first electrode and another end is connected to the second electrode, and including a voltage-division point toward the other end, wherein the resistive element includes a first resistive part including at least a region from the other end to the voltage-division point, and a second resistive part integrally connected to the first resistive part at a position closer to the one end than the first resistive part and having a lower impurity concentration than the first resistive part.

### CROSS-REFERENCE TO RELATED APPLICATION

This application claims benefit of priority under 35 USC 119 based on Japanese Patent Application No. 2024-198916 filed on Nov. 14, 2024, the entire contents of which are incorporated by reference herein.

### BACKGROUND OF THE INVENTION

### 1. Field of the Invention

The present disclosure relates to semiconductor devices.

### 2. Description of the Related Art

High-voltage junction field effect transistors (JFETs) are known as a boot-up element that is a high-voltage device of a boot-up circuit used for conventional switching power supply devices, in which a plurality of source regions are arranged into a circular planar layout along a circumference of an input pad having a circular planar shape (refer to JP2008-153636A). JP 2008-153636A discloses that a JFET and a resistive element are installed on the same semiconductor chip, the resistive element being connected in parallel to the JFET to monitor voltage input to the JFET so as to exhibit voltage sensing. The resistive element is a thin-film resistor including polysilicon (poly-Si), for example, arranged into a spiral planar shape on the voltage blocking structure of the JFET.

JP2017-130484A discloses a semiconductor device having a configuration including a resistive element to which a ground terminal wire and a voltage-division terminal wire are connected on the inner side of the outermost circumference, and including a source electrode wire arranged on a voltage-division resistive part serving as a resistor so as not to be covered, and further having a configuration in which a distance between the source electrode wire and a voltage-division point is kept so as to suppress a variation in resistance value at the voltage-division point derived from a hydrogen absorption effect of titanium (Ti) serving as barrier metal used for the source electrode wire and to thus avoid wrong detection because of a time-course fluctuation of the resistance value.

JP2013-084903A discloses a semiconductor device including a resistive field plate extending from a first electrode toward a second electrode, in which an end part of either the first electrode or the second electrode to which a lower voltage is applied has an impurity concentration of 1×10¹⁸ cm⁻³ or greater.

### SUMMARY OF THE INVENTION

The present disclosure provides a semiconductor device having a configuration capable of decreasing a variation in voltage-division resistance of a resistive element.

An aspect of the present disclosure inheres in a semiconductor device including: a semiconductor substrate; a first semiconductor region provided in the semiconductor substrate; a second semiconductor region provided in the semiconductor substrate; a first electrode electrically connected to the first semiconductor region; a second electrode electrically connected to the second semiconductor region; an insulating film provided on a top surface side of the semiconductor substrate; and a resistive element provided on a top surfaces side of the insulating film, having a structure in which one end is electrically connected to the first electrode and another end is connected to the second electrode, and including a voltage-division point toward the other end, wherein the resistive element includes a first resistive part including at least a region from the other end to the voltage-division point, and a second resistive part integrally connected to the first resistive part at a position closer to the one end than the first resistive part and having a lower impurity concentration than the first resistive part.

### BRIEF DESCRIPTION OF THE DRAWINGS

FIG. 1 is a plan view illustrating a semiconductor device according to a first embodiment;

FIG. 2 is a cross-sectional view taken along line A-A′ in FIG. 1;

FIG. 3 is a cross-sectional view taken along line B-B′ in FIG. 1;

FIG. 4 is a graph showing a relation between a polysilicon-metal distance and a rate of change in a resistance value of a polysilicon resistor;

FIG. 5 is a graph showing a relation between a dose and a sheet resistance;

FIG. 6 is a graph showing a relation between a dose and a rate of variation in resistance value ΔRs;

FIG. 7 is a cross-sectional view illustrating a semiconductor device according to a second embodiment;

FIG. 8 is a plan view illustrating a semiconductor device according to a third embodiment;

FIG. 9 is a cross-sectional view taken along line A-A′ in FIG. 8;

FIG. 10 is a plan view illustrating a semiconductor device according to a fourth embodiment;

FIG. 11 is a plan view illustrating a semiconductor device according to a fifth embodiment;

FIG. 12 is a plan view illustrating a semiconductor device according to a sixth embodiment; and

FIG. 13 is a cross-sectional view taken along line A-A′ in FIG. 12.

### DETAILED DESCRIPTION

With reference to the drawings, first to sixth embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

The first to sixth embodiments described below merely illustrate schematically devices and methods for specifying and giving shapes to the technical idea of the present disclosure, and the span of the technical idea is not limited to materials, shapes, structures, and relative positions of elements described herein.

In the specification, definitions of directions such as an up-and-down direction and a right-and-left direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is an exemplified case where a first conductivity-type is a p-type and a second conductivity-type is an n-type. However, the relationship of the conductivity-types may be inverted to set the first conductivity-type to the n-type and the second conductivity-type to the p-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type”, “second conductivity-type”, “n-type” and “p-type” in the following description indicate the members and the regions formed of semiconductor materials without particular obvious limitations.

### First Embodiment

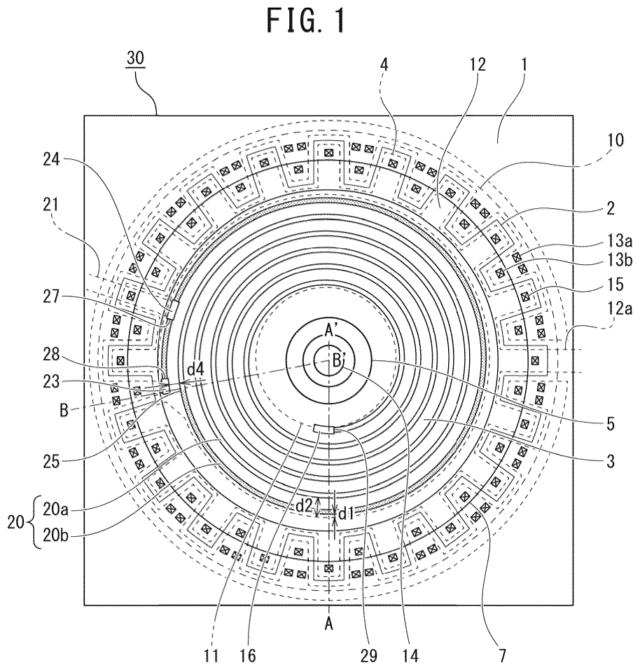

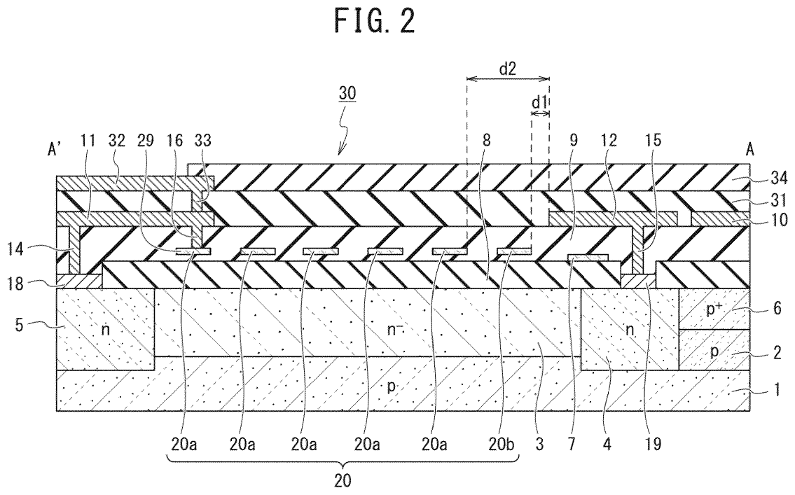

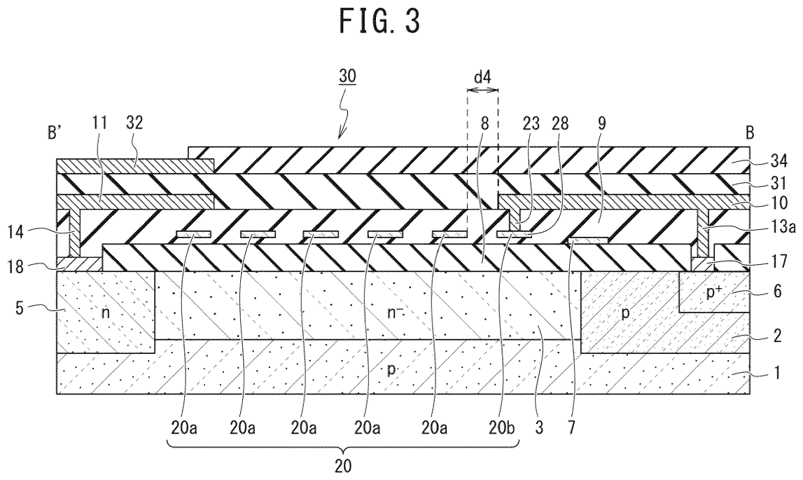

FIG. 1 is a plan view illustrating a semiconductor device according to a first embodiment. FIG. 2 is a cross-sectional view taken along line A-A′ in FIG. 1. FIG. 3 is a cross-sectional view taken along line B-B′ in FIG. 1.

As illustrated in FIG. 1 to FIG. 3, the semiconductor device according to the first embodiment is an integrated circuit (IC) including a high-voltage junction field effect transistor (JFET) 30 and a resistive element 20 provided on the JFET 30 so as to be integrated together on the same semiconductor chip (a semiconductor substrate) 1. The JFET 30 is a boot-up element in a boot-up circuit used for a switching power-supply device (not illustrated). The resistive element 20 monitors voltage input to the JFET 30 (for voltage sensing), so as to exhibit a brownout function and the like.

As illustrated in FIG. 2 and FIG. 3, the JFET 30 is provided in the semiconductor substrate 1 of a first conductivity-type (p-type). The semiconductor substrate 1 is a silicon (Si) substrate, for example. The semiconductor substrate 1 may include silicon carbide (SiC), gallium nitride (GaN), gallium arsenide (GaAs), gallium oxide (Ga₂O₃), diamond (C), or the like. The semiconductor substrate 1 may include a substrate and an epitaxial growth layer epitaxially grown on the substrate.

A semiconductor region (a drain region) 5 of a second conductivity-type (n-type) is selectively provided at an upper part of the semiconductor substrate 1. A semiconductor region (a drift region) 3 of n⁻-type having a lower impurity concentration than the drain region 5 is selectively provided at an upper part of the semiconductor substrate 1 so as to be in contact with the drain region 5. A semiconductor region (a source region) 4 of n-type having a higher impurity concentration than the drift region 3 is selectively provided at an upper part of the semiconductor substrate 1 separately from the drain region 5. The source region 4 is in contact with the drift region 3 and is opposed to the drain region 5 with the drift region 3 interposed. The present embodiment is illustrated with the case in which the source region 4 and the drain region 5 are each provided to have a greater depth than the drift region 3, but is not limited to this case. The source region 4 and the drain region 5 may each have a shallower depth than the drift region 3, or may each have the same depth as the drift region 3.

As illustrated in FIG. 2, a semiconductor region (a gate region) 2 of p-type is selectively provided at an upper part of the semiconductor substrate 1 so as to be in contact with the source region 4. Although FIG. 2 illustrates the cross section in which the gate region 2 is not in contact with the drift region 3, the gate region 2 is in contact with the drift region 3 in the cross section in FIG. 3. A semiconductor region (a contact region) 6 of p⁺-type having a higher impurity concentration than the gate region 2 is selectively provided at an upper part of the gate region 2 so as to be in contact with the gate region 2, as illustrated in FIG. 2 and FIG. 3. The present embodiment is illustrated with the case in which the gate region 2 is provided to have a greater depth than the drift region 3, but is not limited to this case. The gate region 2 may have a shallower depth than the drift region 3, or may have the same depth as the drift region 3.

As illustrated in FIG. 1, the drain region 5 has a substantially circular planar shape. The drift region 3 is provided to surround the circumference of the drain region 5. The drift region 3 has a gear-like planar shape, for example, and partly enters the gate region 2 (at 20 parts, for example) so as to each have a predetermined width. The source region 4 is divided into plural parts on the circumference of the circle each having the common distance from the drain region 5 so as to be located in the individual parts of the drift region 3 entering the gear-shaped gate region 2. The gate region 2 thus has a planar shape interposing the respective parts of the source region 4 in a direction perpendicular to a direction connecting the source region 4 and the drain region 5. The gate region 2 interposing the respective parts of the source region 4 extends from the position on the outside of the source region 4 to a part on the inside of the source region 4 toward the drain region 5.

As illustrated in FIG. 2 and FIG. 3, an element-separation insulating film (an insulating film) 8 such as a film of local oxidation of silicon (a LOCOS film) is provided on the drift region 3. A gate polysilicon electrode 7 is provided on the element-separation insulating film 8. As illustrated in FIG. 1, the gate polysilicon electrode 7 has a ring-like planar shape so as to be arranged across the part at which the drift region 3 and the gate region 2 are in contact with each other. The gate polysilicon electrode 7 is electrically connected to a gate electrode wire 10 described below via a gate polysilicon contact part 13b. The gate polysilicon electrode 7 has a function of expanding a depletion layer extending from a p-n junction between the gate region 2 and the source region 4 when a potential of a source electrode wire 12 described below is increased to lead the p-n junction to be reversely biased. This avoids an increase in the potential of the source electrode wire 12.

As illustrated in FIG. 2 and FIG. 3, an interlayer insulating film (an insulating film) 9 is provided to cover the element-separation insulating film 8, the gate polysilicon electrode 7, the contact region 6, the source region 4, and the drain region 5. A drain electrode wire (a drain electrode) 11, the source electrode wire (a source electrode) 12, and the gate electrode wire (a gate electrode) 10, which are metal wires (electrodes), are provided on the interlayer insulating film 9. FIG. 1 schematically indicates the drain electrode wire 11, the source electrode wire 12, and the gate electrode wire 10 by the broken lines.

As illustrated in FIG. 1, the drain electrode wire 11 has a substantially circular planar shape concentric with the drain region 5. As illustrated in FIG. 2 and FIG. 3, the drain electrode wire 11 is opposed to the drain region 5 in the depth direction with the interlayer insulating film 9 interposed. The drain electrode wire 11 is electrically connected to the drain region 5 via a drain contact part 14 penetrating the interlayer insulating film 9 and a contact plug 18 which is a semiconductor region of n⁺⁺-type. The drain electrode wire 11 extends to protrude to the outside over the interlayer insulating film 9, and is opposed to the innermost circumferential part of the resistive element 20 in the depth direction with the interlayer insulating film 9 interposed. As illustrated in FIG. 2, the drain electrode wire 11 is electrically connected to an end part 29 of the resistive element 20 on the inner circumferential side via a resistive element contact part 16 penetrating the interlayer insulating film 9.

As illustrated in FIG. 1, the gate electrode wire 10 has a substantially ring-like planar shape. The ring-shaped outer circumference of the gate electrode wire 10 has a substantially circular shape concentric with the drain region 5. The ring-shaped inner circumference of the gate electrode wire 10 projects to the inside (toward the drain region 5) to have a predetermined width so as to conform to the shape of the drift region 3 formed into the gear-like shape and the source region 4. As illustrated in FIG. 2 and FIG. 3, the gate electrode wire 10 is opposed to the gate region 2 in the depth direction with the interlayer insulating film 9 interposed. As illustrated in FIG. 3, the gate electrode wire 10 is electrically connected to the contact region 6 via a gate contact part 13a penetrating the interlayer insulating film 9 and a contact plug 17 which is a semiconductor region of p⁺⁺-type. A ground potential is applied to the gate electrode wire 10 so as to be constantly grounded.

As illustrated in FIG. 1, the source electrode wire 12 has a substantially ring-like planar shape, and is cut off at a position adjacent to an end part 28 of the resistive element 20 on the outer circumferential side. The ring-shaped outer circumference of the source electrode wire 12 is separated from the gate electrode wire 10 and projects to the outside to have a predetermined width so as to conform to the shape of the drift region 3 formed into the gear-like shape and the source region 4. The source electrode wire 12 is connected with a drawn line 12a to be electrically connected to the outside. While FIG. 1 illustrates the case in which the drawn line 12a is located on the right side in FIG. 1, the position of the drawn line 12a can be changed as appropriate. The number of the drawn lines connected to the source electrode wire 12 can also be determined as appropriate.

As illustrated in FIG. 2, the source electrode wire 12 is opposed to the source region 4 in the depth direction with the interlayer insulating film 9 interposed. The source electrode wire 12 is electrically connected to the source region 4 via a source contact part 15 penetrating the interlayer insulating film 9 and a contact plug 19 which is a semiconductor region of n⁺⁺-type. The source electrode wire 12 extends to protrude toward the inside over the interlayer insulating film 9 so as to be opposed to the gate polysilicon electrode 7 in the depth direction with the interlayer insulating film 9 interposed.

The metal wires of the gate electrode wire 10, the drain electrode wire 11, and the source electrode wire 12 are each made of a stacked metal film including barrier metal, an aluminum (Al) metal film, and a reflection-preventing film sequentially stacked in this order. The parts of the stacked metal film buried in contact holes serve as the gate contact part 13a, the drain contact part 14, the source contact part 15, and the resistive element contact part 16. The contact plug 17, the contact plug 18, and the contact plug 19 are each made of stacked metal film including barrier metal and a tungsten (W) film sequentially stacked. The term “aluminum metal film” as used herein refers to a metal film including aluminum, and may be an aluminum-copper (Al—Cu) film or an aluminum-silicon-copper (Al—Si—Cu) film, for example.

The barrier metal used for the gate electrode wire 10, the drain electrode wire 11, the source electrode wire 12, and the like has a function capable of preventing diffusion of metal atoms toward the semiconductor substrate 1 and a mutual reaction between the semiconductor substrate 1 and the metal film. The barrier metal may be a stacked film including a titanium (Ti) film and a titanium nitride (TiN) film sequentially stacked, for example. The barrier metal used for the contact plug 17, the contact plug 18, and the contact plug 19 is subjected to silicidation (reduction in resistance) through a rection with a semiconductor part. The refection-preventing film may be a stacked film including a titanium film and a titanium nitride film sequentially stacked. The reflection-preventing film has a function capable of preventing diffused reflection of light on the aluminum metal film during exposure of a photoresist mask for delineation used for the aluminum metal film. The respective metal wires of the gate electrode wire 10, the drain electrode wire 11, and the source electrode wire 12 thus can include titanium (Ti) in the barrier metal or the reflection-preventing film.

The metal wires of the gate electrode wire 10, the drain electrode wire 11, and the source electrode wire 12 may each be a multi-layer wire. FIG. 2 illustrates a case in which the drain electrode wires 11 and 32 are each a multi-layer wire. An interlayer insulating film (an insulating film) 31 is provided on the interlayer insulating film 9, the gate electrode wire 10, and the drain electrode wire 11 that is the first layer and the source electrode wire 12. The drain electrode wire 32 that is the second layer is provided on the interlayer insulating film 31 so as to be opposed to the drain electrode wire 11 of the first layer in the depth direction with the interlayer insulating film 31 interposed. The drain electrode wire 32 of the second layer is electrically connected to the drain electrode wire 11 of the first layer via the drain contact part 33 penetrating the interlayer insulating film 31. An interlayer insulating film (an insulating film) 34 is provided on the drain electrode wire 32 and the interlayer insulating film 31.

As illustrated in FIG. 1, the resistive element 20 is arranged so as to surround the circumference of the drain region 5. The end part 29 of the resistive element 20 on the inner circumferential side is electrically connected to the drain electrode wire 11 applied with a drain potential (a first potential). The end part 28 of the resistive element 20 on the outer circumferential side is electrically connected to the gate electrode wire 10 having a lower potential than the drain electrode wire 11 and applied with a ground potential (a second potential) lower than the drain potential (the first potential).

The resistive element 20 is a thin-film resistor such as a polysilicon resistor including polysilicon doped with impurities such as phosphorus (P), boron (B), and boron fluorine (BF₂), for example. The resistive element 20 has a spiral planar shape. While FIG. 1 illustrates the case in which the resistive element 20 is formed into a right-handed (clockwise) spiral shape toward the outer circumference, the resistive element 20 may be formed into a left-handed (counterclockwise) spiral shape instead. FIG. 1 also illustrates the case in which the resistive element 20 has a substantially circular outline, but the present embodiment is not limited to this case. The outline of the resistive element 20 may be either a substantially oval shape or a substantially racetrack-like shape, for example.

As illustrated in FIG. 2 and FIG. 3, the resistive element 20 is buried inside the interlayer insulating film 9 on the top surface side of the element-separation insulating film 8 provided on the semiconductor substrate 1. The resistive element 20 is opposed to the drift region 3 in the depth direction with the element-separation insulating film 8 interposed. The resistive element 20 is located on the inner side of the gate polysilicon electrode 7 separately from each other. As illustrated in FIG. 2, the end part 29 of the resistive element 20 on the inner circumferential side is electrically connected to the drain electrode wire 11 via the resistive element contact part 16.

The innermost diameter of the resistive element 20 is defined to be smaller than the diameter of the drain electrode wire 11 to a certain extent sufficient to arrange the resistive element contact part 16 provided for the connection to the drain electrode wire 11. The outermost diameter of the resistive element 20 is smaller than the inner diameter of the source electrode wire 12 so as not to overlap with the source electrode wire 12. The present embodiment does not necessarily avoid the overlap of the resistive element 20 with the source electrode wire 12. In addition, the outermost diameter of the resistive element 20 may conform to the inner diameter of the source electrode wire 12, or may be greater than the inner diameter of the source electrode wire 12.

As illustrated in FIG. 1, the substantially ring-like planar shape of the source electrode wire 12 is cut off at the position adjacent to the end part 28 of the resistive element 20 on the outer circumferential side. As illustrated in FIG. 3, the end part 28 of the resistive element 20 on the outer circumferential side is connected to the gate electrode wire 10 via a ground contact part 23 penetrating the interlayer insulating film 9. The ground contact part 23 may be connected to a ground terminal wire (a ground electrode) different from the gate electrode wire 10 so that the ground terminal wire is extracted to the outside to be grounded.

As illustrated in FIG. 1, the resistive element 20 is connected to a voltage-division terminal wire 21 via a voltage-division-point contact part 24 penetrating the interlayer insulating film 9 at a voltage-division point 27 on the inner circumferential side of the outermost end part 28 connected to the ground contact part 23. The voltage-division terminal wire 21 serves as a terminal for sensing voltage input to an input pad of the JFET 30, and divides to output the input voltage to a voltage sensing circuit. As the voltage-division point 27 is closer to the inside of the spiral, the potential of the voltage-division terminal wire 21 output to the voltage sensing circuit is higher. The voltage-division point 27 is thus arranged at a position capable of dividing the voltage input to the input pad of the JFET 30 to less than a breakdown voltage of the voltage sensing circuit. For example, the voltage-division point 27 is arranged at a position at which a potential that is 1/100 of the voltage input to the input pad of the JFET 30 is extracted.

The voltage-division terminal wire 21 may be extracted to the outside at the position at which the substantially ring-like shape of the source electrode wire 12 and the gate electrode wire 10 is cut off (not illustrated). The voltage-division terminal wire 21 may be arranged at the same layer level as the source electrode wire 12 and the gate electrode wire 10. The voltage-division terminal wire 21 may include the same material as the source electrode wire 12 and the gate electrode wire 10. The voltage-division terminal wire 21 may be arranged at a layer level different from the source electrode wire 12 and the gate electrode wire 10. For example, the source electrode wire 12 and the gate electrode wire 10 may be arranged at the first layer level of the multi-layer wire, and the voltage-division terminal wire 21 may be arranged at the second layer level of the multi-layered wire.

The configuration of the JFET 30 as described above determines whether to turn OFF the JFET 30 depending on the potential of the voltage-division terminal wire 21. For example, the determination is made such that the potential of the source electrode wire 12 is increased by the voltage sensing circuit (not illustrated) electrically connected to the source electrode wire 12 in accordance with the potential of the voltage-division terminal wire 21 so as to lead the p-n junction between the source region 4 and the gate region 2 to be reverse biased. This configuration connects a depletion layer expanding from the gate region 2 on both sides of the source region 4 at the frontage between the source region 4 and the drift region 3, which is the interface between the source region 4 and the drift region 3, so as to cut off the current connection of the JFET 30 to turn OFF the JFET 30 accordingly.

The semiconductor device according to the first embodiment has the configuration in which the source electrode wire 12 that is the metal wire is opposed to the outermost circumference of the resistive element 20, as illustrated in FIG. 1. The source electrode wire 12 is opposed to the outermost circumference of the resistive element 20 halfway around or more, along substantially the entire outermost circumference of the resistive element 20.

A presumed case is described below in which an impurity concentration in the resistive element 20 is entirely constant and a sheet resistance is also constant. If the impurity concentration in the resistive element 20 is decreased and the sheet resistance of the resistive element 20 is increased to a level of about eight kΩ/sq, for example, the metal wire such as the source electrode wire 12 is only led to be arranged closer to the resistive element 20, and a shift in resistance value derived from a hydrogen absorption effect of titanium (Ti) included in the metal wire is then caused, inducing a variation in the resistance value (a variation in the voltage-division resistance) at the voltage-division point 27 accordingly.

In particular, a manufacturing process for the semiconductor device according to the first embodiment executes hydrogen annealing as heat treatment in a hydrogen gas atmosphere in order to terminate a dangling bond on the surface of the resistive element 20 by hydrogen atoms. If the metal wire such as the source electrode wire 12 is arranged close to the resistive element 20, Ti included in the barrier metal of the metal wire absorbs the hydrogen atoms, which impedes the termination of the dangling bond on the surface of the resistive element 20 by the hydrogen atoms, resulting in a variation in the resistance value.

To suppress such a variation in the voltage-division resistance of the resistive element 20 as described above, the semiconductor device according to the first embodiment has a structure in which the resistive element 20 includes a resistive part (a low-specific-resistive part) 20b including at least a region between one end (the end part) 28 of the resistive element 20 on the outer side (on the outer circumferential side) and the voltage-division point 27, and a resistive part (a high-specific-resistive part) 20a integrally connected to the resistive part 20b at a position closer to the end part on the inner side (on the inner circumferential side) than the resistive part 20b and having a lower impurity concentration than the resistive part 20b. FIG. 1 schematically indicates the resistive part 20b with dot hatching for facilitation of distinction between the resistive part 20a and the resistive part 20b.

The ground contact part 23 is connected to the end part 28 of the resistive element 20 on the outer circumferential side. The voltage-division-point contact part 24 is connected to the voltage-division point 27 of the resistive part 20b. While FIG. 1 illustrates the case in which the resistive part 20b has a length of about one round of the spiral-shaped resistive element 20, the length of the resistive part 20b is not limited to this case, and may be either shorter than one round or equal to or longer than one round of the spiral-shaped resistive element 20. A boundary position 25 between the resistive part 20a and the resistive part 20b can also be changed as appropriate.

A distance d1 between the outer circumference of the resistive part 20b and the source electrode wire 12 as illustrated in FIG. 1 and FIG. 2 is at least partly set to a predetermined distance or smaller, which is about four micrometers or smaller, for example. The distance d1 between the outer circumference of the resistive part 20b and the source electrode wire 12 may be entirely set to four micrometers or smaller. Alternatively, the distance d1 between the outer circumference of the resistive part 20b and the source electrode wire 12 may be partly set to four micrometers or smaller, while the rest of the distance d1 may be greater than four micrometers, for example.

The resistive part 20a includes the region from the boundary position 25 between the resistive part 20a and the resistive part 20b to the other end (the end part) 29 of the resistive element 20 on the inner side (on the inner circumferential side). For example, as illustrated in FIG. 1 and FIG. 2, a distance d2 between the outer circumference of the resistive part 20a and the source electrode wire 12 is set to greater than about four micrometers, which is an example of the predetermined distance described above. In addition, as illustrated in FIG. 1 and FIG. 3, a distance d4 between the outer circumference of the resistive part 20a and the gate electrode wire 10 is greater than about four micrometers.

The resistive part 20b has a higher impurity concentration than the resistive part 20a. The impurity concentration of the resistive part 20b is set in a range of about 1×10¹⁷ cm⁻³ or higher and 1×10²¹ cm⁻³ or lower, for example. The impurity concentration of the resistive part 20a is set in a range of about 1×10¹⁶ cm⁻³ or higher and 1×10²⁰ cm⁻³ or lower, for example.

The resistive part 20b has a lower sheet resistance than the resistive part 20a. The sheet resistance of the resistive part 20 b is set in a range of about 100 Ω/sq or greater and 2 kΩ/sq or smaller, and may be about 400 Ω/sq. The sheet resistance of the resistive part 20a is set in a range of about 2 kΩ/sq or greater and 10 kΩ/sq or smaller, and may be about 8 kΩ/sq.

The resistive part 20a and the resistive part 20b can be formed by independent local impurity implantation, followed by annealing. The resistive part 20a may be formed by ion implantation into the entire polysilicon including the region to be provided with the resistive part 20b, or may be formed by selective ion implantation by use of a photoresist mask. The resistive part 20b is formed by selective ion implantation by use of a photoresist mask so as to have a larger dose (total dose) of impurities implanted into the resistive part 20b than that implanted into the resistive part 20a. The resistive part 20b may be formed either by single ion implantation or by ion implantation repeatedly executed several times including the ion implantation for forming the resistive part 20a.

The dose (the total does) of the impurities implanted into the resistive part 20b is set in a range of about 5×10¹⁴ cm⁻² or greater and 3×10¹⁵ cm⁻² or smaller, for example, and may be set to about 5×10¹⁴ cm⁻². The dose of impurities implanted into the resistive part 20a is set in a range of about 1×10¹⁴ cm⁻² or greater and 5×10¹⁴ cm⁻² or smaller, for example, and may be set to about 2×10¹⁴ Cm⁻².

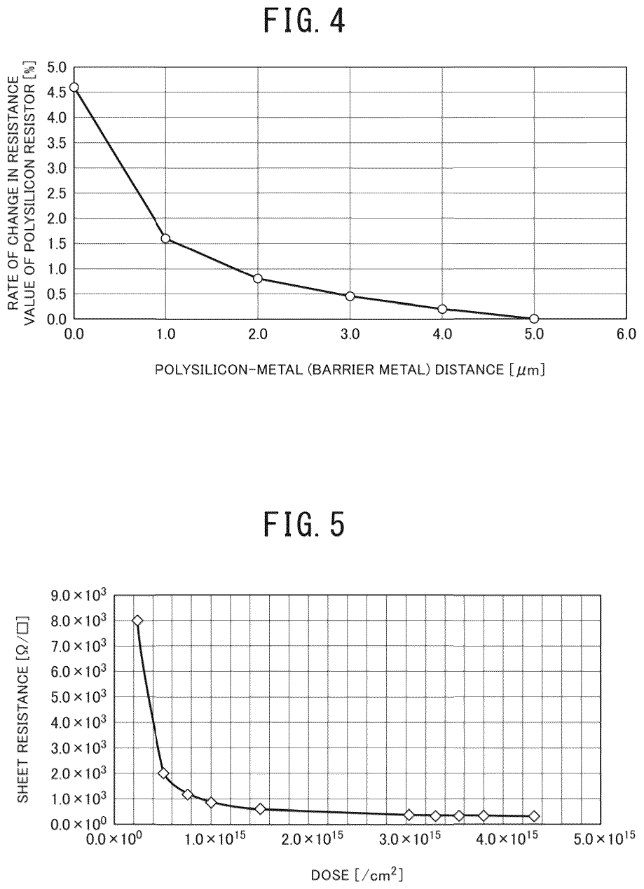

FIG. 4 is a graph showing a relation between a distance between the polysilicon resistor and the metal wire and a rate of change in the resistance value of the polysilicon resistor. The axis of abscissas of the graph in FIG. 4 indicates the distance between the polysilicon resistor and the metal wire, and the axis of ordinates indicates the rate of change in the resistance value of the polysilicon resistor. As shown in FIG. 4, the rate of change in the resistance value of the polysilicon resistor increases as the distance between the polysilicon resistor and the metal wire decreases to about four micrometers or smaller. The effects of the semiconductor device according to the first embodiment for suppressing the variation in the voltage-division resistance are thus effective particularly when the distance between the polysilicon resistor and the metal wire decreases to about four micrometers or smaller.

FIG. 5 is a graph showing a relation between the dose of the impurities implanted into the polysilicon resistor and the sheet resistance of the polysilicon resistor. The axis of abscissas of the graph in FIG. 5 indicates the dose of the impurities implanted into the polysilicon resistor, and the axis of ordinates indicates the sheet resistance of the polysilicon resistor. As shown in FIG. 5, the increase in the sheet resistance is significant when the dose of the impurities is 5×10¹⁴ cm⁻² or smaller and the sheet resistance is 2 kΩ/sq or higher. The effects of the semiconductor device according to the first embodiment for suppressing the variation in the voltage-division resistance are thus effective particularly when the dose of the impurities implanted into the polysilicon resistor is 5×10¹⁴ cm⁻² or smaller and the sheet resistance is 2 kΩ/sq or higher.

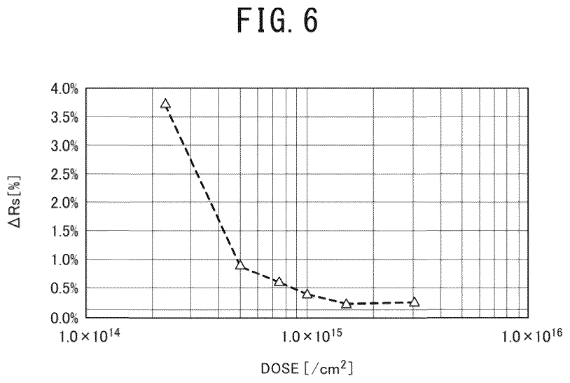

FIG. 6 is a graph showing a relation between the dose of the impurities implanted into the polysilicon resistor and a variation in the sheet resistance. The axis of abscissas in FIG. 6 indicates the dose of the impurities implanted into the polysilicon resistor, and the axis of ordinates indicates a variation ratio ΔRs of the sheet resistance in the polysilicon resistor when the source electrode wire 12 is provided on the polysilicon resistor with respect to the sheet resistance in the polysilicon resistor when the source electrode wire 12 is not provided on the polysilicon resistor. As shown in FIG. 6, the variation ratio ΔRs significantly increases when the dose of the impurities is 5×10¹⁴ cm⁻² or smaller. The effects of the semiconductor device according to the first embodiment for suppressing the variation in the voltage-division resistance are thus effective particularly when the dose of the impurities implanted into the polysilicon resistor is 5×10¹⁴ cm⁻² or smaller.

The semiconductor device according to the first embodiment as described above has the configuration including the resistive element 20 for sensing provided on the JFET 30, in which the resistive part 20b including the region between the end part 28 on the low potential side and the voltage-division point 27 has the higher impurity concentration than the resistive part 20a, and has the lower sheet resistance than the resistive part 20a. This configuration can decrease an influence of the dangling bond with respect to the polysilicon derived from the hydrogen termination effect due to the hydrogen annealing treatment during the manufacturing process or the movement of hydrogen in the passivation film or in the interlayer insulating film in the actual active environment, so as to suppress or reduce the variation in the voltage-division resistance. The semiconductor device thus can ensure long-term reliability with a stable voltage-division ratio.

Further, the configuration according to the present embodiment does not need to provide an invalid region serving as a dummy resistive part on the outer circumferential side of the resistive element 20 in order to reduce the variation in the voltage-division resistance, and thus can lead the outermost circumference of the resistive element 20 to totally serve as a resistive part, so as to increase the total polysilicon resistance value (the total resistance value). This configuration can contribute to low-standby power consumption, and thus achieve a voltage-division resistive element with a lower initial variation or a lower fluctuation in reliability accordingly.

### Second Embodiment

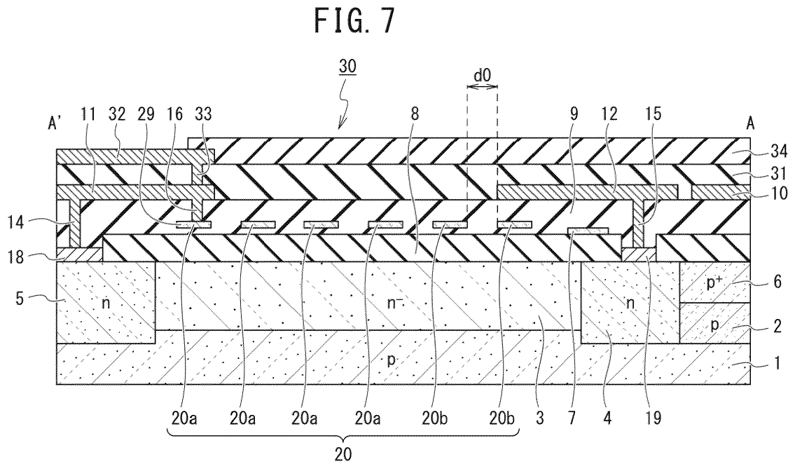

FIG. 7 is a cross-sectional view illustrating a semiconductor device according to a second embodiment, corresponding to the cross section taken along line A-A′ in FIG. 1. As illustrated in FIG. 7, the semiconductor device according to the second embodiment differs from the semiconductor device according to the first embodiment illustrated in FIG. 2 in that the source electrode wire 12 extends further to the inner side.

The resistive part 20b at the outermost circumference of the resistive element 20 illustrated in FIG. 7 is located under and covered with the source electrode wire 12 with the interlayer insulating film 9 interposed. A distance d0 between the outer circumference of the second outermost resistive part 20b of the resistive element 20 and the source electrode wire 12 illustrated in FIG. 7 is set to a predetermined distance or smaller, which is about four micrometers or smaller, for example. The other configurations of the semiconductor device according to the second embodiment are substantially the same as those of the semiconductor device according to the first embodiment, and overlapping explanations are not repeated below.

The semiconductor device according to the second embodiment has the configuration in which the part of the resistive element 20 on the outer circumferential side overlapping with the metal wire such as the source electrode wire 12 and also the part with the distance d0 from the metal wire that is the predetermined distance or smaller (four micrometers or smaller, for example) each serve as the resistive part 20b with the relatively high impurity concentration, regardless of whether the resistive element 20 on the outer circumferential side overlaps with the metal wire in the depth direction. This configuration can suppress or reduce the variation in the voltage-division resistance.

### Third Embodiment

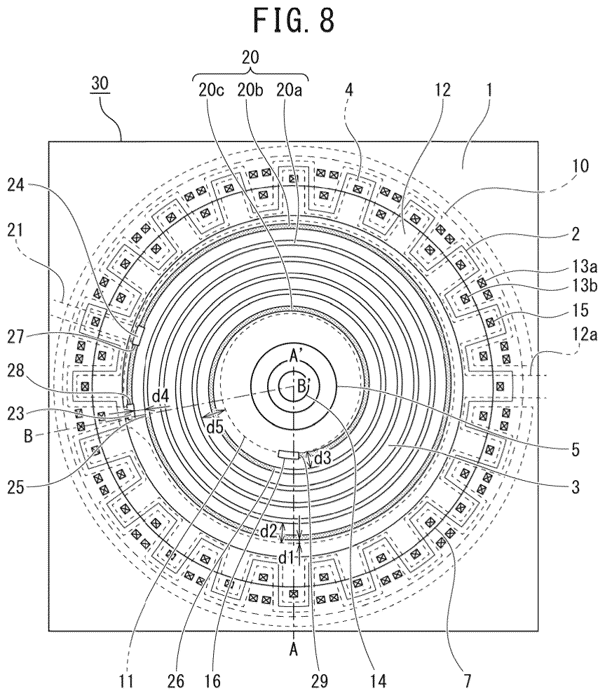

FIG. 8 is a plan view illustrating a semiconductor device according to a third embodiment. As illustrated in FIG. 8, the semiconductor device according to the third embodiment differs from the semiconductor device according to the first embodiment in that the resistive element 20 further includes a resistive part (a low-specific-resistive part) 20c integrally connected to the resistive part 20a at a position closer to the end part on the inner circumferential side than the resistive part 20a and having a higher impurity concentration and higher sheet resistance than the resistive part 20a. FIG. 8 schematically indicates the resistive part 20b and the resistive part 20c with dot hatching for facilitation of distinction between the resistive part 20a, the resistive part 20b, and the resistive part 20c.

The semiconductor device according to the third embodiment has a configuration in which the part of the resistive element 20 on the inner circumferential side having a predetermined distance or smaller (four micrometers or smaller, for example) from the metal wire such as the drain electrode wire 11 serves as the resistive part 20c having a relatively high impurity concentration. The resistive part 20c includes at least the end part 29 of the resistive element 20 on the inner circumferential side. The resistive part 20c has a length that can be determined as appropriate, and may have either a length of less than one round or a length of one round or greater of the spiral-shaped resistive element 20. A boundary position 26 between the resistive part 20c and the resistive part 20a can also be changed as appropriate.

The impurity concentration of the resistive part 20c is higher than that of the resistive part 20a. The resistive part 20c may have substantially the same impurity concentration as the resistive part 20b, or may have either a higher impurity concentration or a lower impurity concentration than the resistive part 20b. The sheet resistance of the resistive part 20c is smaller than that of the resistive part 20a. The resistive part 20c may have substantially the same sheet resistance as the resistive part 20b, or may have either a higher sheet resistance or a lower sheet resistance than the resistive part 20b.

A dose of impurities implanted into the resistive part 20c is greater than that of the resistive part 20a. The resistive part 20c may have substantially the same dose of impurities as the resistive part 20b, or may have either a higher dose of impurities or a lower dose of impurities than the resistive part 20b. The resistive part 20c may be formed such that the impurity ions are implanted into a region serving as the resistive part 20c simultaneously with the ion implantation for the formation of the resistive part 20b, for example.

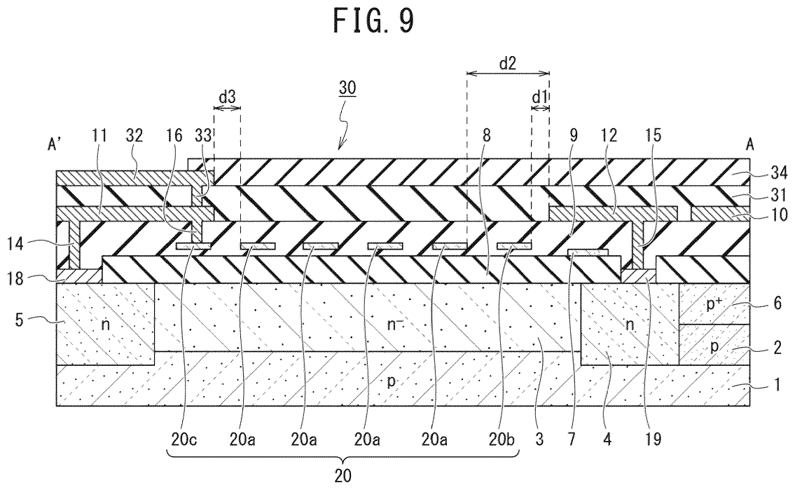

FIG. 9 is a cross-sectional view taken along line A-A′ in FIG. 8. The resistive part 20c provided at the innermost circumference of the resistive element 20 is located under the drain electrode wire 11. As illustrated in FIG. 8 and FIG. 9, distances d3 and d5 each defined between the resistive part 20a located on the outer circumferential side of the resistive part 20c and the drain electrode wire 11 are greater than four micrometers, which is an example of the predetermined distance described above. The other configurations of the semiconductor device according to the third embodiment are substantially the same as those of the semiconductor device according to the first embodiment, and overlapping explanations are not repeated below.

The semiconductor device according to the third embodiment has the configuration in which the part of the resistive element 20 on the outer circumferential side serves as the resistive part 20b with the relatively high impurity concentration. This configuration can suppress or reduce the variation in the voltage-division resistance. Further, the semiconductor device has the configuration in which the part of the resistive element 20 on the inner circumferential side serves as the resistive part 20c with the relatively high impurity concentration. This configuration can suppress or reduce the variation in the resistance value at the position on the high-potential side of the resistive element 20 located adjacent to the metal wire such as the drain electrode wire 11.

### Fourth Embodiment

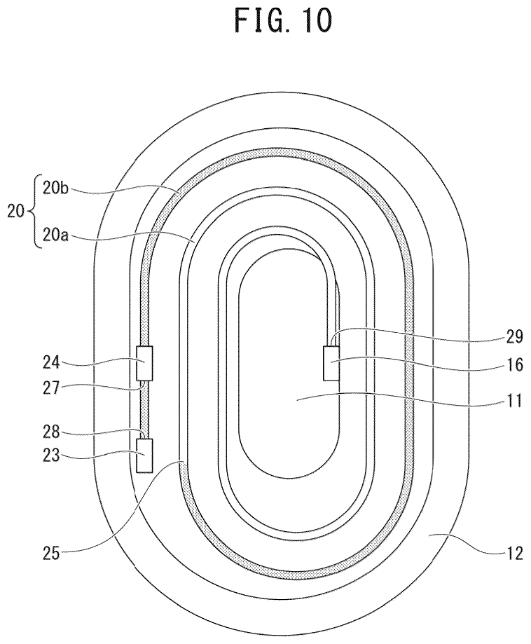

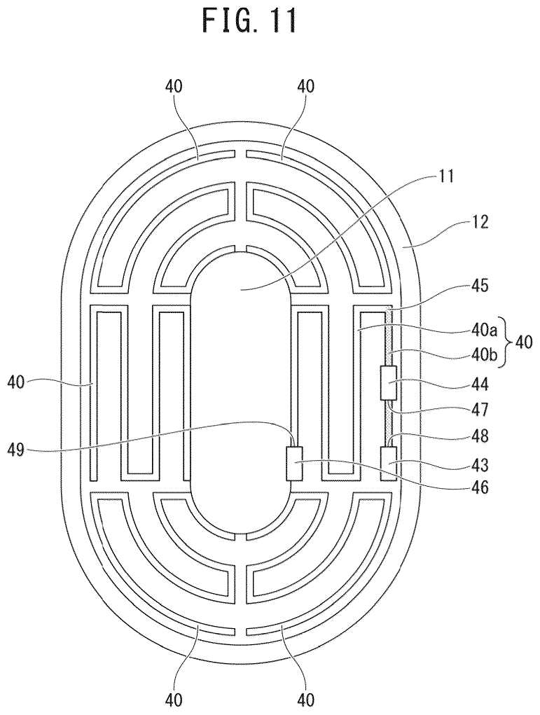

FIG. 10 is a plan view illustrating a semiconductor device according to a fourth embodiment. FIG. 10 illustrates some of the constituent elements of the semiconductor device according to the fourth embodiment, particularly illustrating the resistive element 20, the drain electrode wire 11, and the source electrode wire 12, while omitting the illustration of the other elements. As illustrated in FIG. 10, the semiconductor device according to the fourth embodiment has the same configuration as the semiconductor device according to the first embodiment illustrated in FIG. 1 in that the resistive element 20 has the spiral planar pattern, but differs from the semiconductor device according to the first embodiment in that the resistive element 20 has a racetrack-like planar outline. FIG. 10 schematically indicates the resistive part 20b with dot hatching for facilitation of distinction between the resistive part 20a and the resistive part 20b.

As illustrated in FIG. 10, the resistive element 20 includes straight parts extending parallel to each other, and curved parts (corner parts) connecting the respective straight parts. The resistive element contact part 16 is electrically connected to the end part 29 of the resistive element 20 on the inner side (on the inner circumferential side). The ground contact part 23 is electrically connected to the end part 28 of the resistive element 20 on the outer side (on the outer circumferential side). The voltage-division-point contact part 24 is electrically connected to the voltage-division point 27 located at a position closer to the inner end of the resistive element 20 than the ground contact part 23. The other configurations of the semiconductor device according to the fourth embodiment are substantially the same as those of the semiconductor device according to the first embodiment, and overlapping explanations are not repeated below.

The semiconductor device according to the fourth embodiment has the configuration in which the part of the resistive element 20 on the outer circumferential side serves as the resistive part 20b with the relatively high impurity concentration, as in the case of the semiconductor device according to the first embodiment, regardless of whether the resistive element 20 has the racetrack-like planar outline. This configuration can suppress or reduce the variation in the voltage-division resistance.

### Fifth Embodiment

FIG. 11 is a plan view illustrating a semiconductor device according to a fifth embodiment. FIG. 11 illustrates some of the constituent elements of the semiconductor device according to the fifth embodiment, particularly illustrating a resistive element 40, the drain electrode wire 11, and the source electrode wire 12, while omitting the illustration of the other elements. As illustrated in FIG. 11, the semiconductor device according to the fifth embodiment differs from the semiconductor device according to the first embodiment illustrated in FIG. 1 in that the resistive element 40 has a meandering planar shape. The present embodiment is illustrated with the case in which the resistive element 40 has a racetrack-like planar outline, but is not limited to this case. While FIG. 11 illustrates the case in which the resistive element 40 is divided into plural (six) parts, the number of the resistive elements can be changed as appropriate, and the present embodiment may include only the single resistive element. The respective resistive elements 40 are formed into the meandering shape so as to have folded-over parts.

The explanations are made in more detail below with regard to one of the resistive elements 40 particularly located at the right-middle part in FIG. 11. A resistive element contact part 46 is electrically connected to the end part 49 of the resistive element 40 on the inner side. A ground contact part 43 is electrically connected to the end part 48 of the resistive element 40 on the outer side. The voltage-division-point contact part 44 is electrically connected to a voltage-division point 47 located at a position closer to the inner end of the resistive element 40 than the ground contact part 43.

The resistive element 40 is a thin-film resistor such as a polysilicon resistor including polysilicon doped with impurities. The resistive element 40 includes a resistive part (a low-specific-resistive part) 40b including at least a region between the end part 48 of the resistive element 40 on the outer side and the voltage-division point 47, and a resistive part (a high-specific-resistive part) 40a integrally connected to the resistive part 40b at a position closer to the end part on the inner side than the resistive part 40b and having a lower impurity concentration and higher sheet resistance than the resistive part 40b. FIG. 11 schematically indicates the resistive part 40b with dot hatching for facilitation of distinction between the resistive part 40a and the resistive part 40b. The other resistive elements 40 have substantially the same configuration as the resistive element 40 located at the right-middle part in FIG. 11. The other configurations of the semiconductor device according to the fifth embodiment are substantially the same as those of the semiconductor device according to the first embodiment, and overlapping explanations are not repeated below.

The semiconductor device according to the fifth embodiment has the configuration in which the part of the resistive element 40 on the outer side that is the low-potential side serves as the resistive part 40b with the relatively high impurity concentration, as in the case of the semiconductor device according to the first embodiment, regardless of whether the resistive element 40 has the meandering planar shape. This configuration can suppress or reduce the variation in the voltage-division resistance.

### Sixth Embodiment

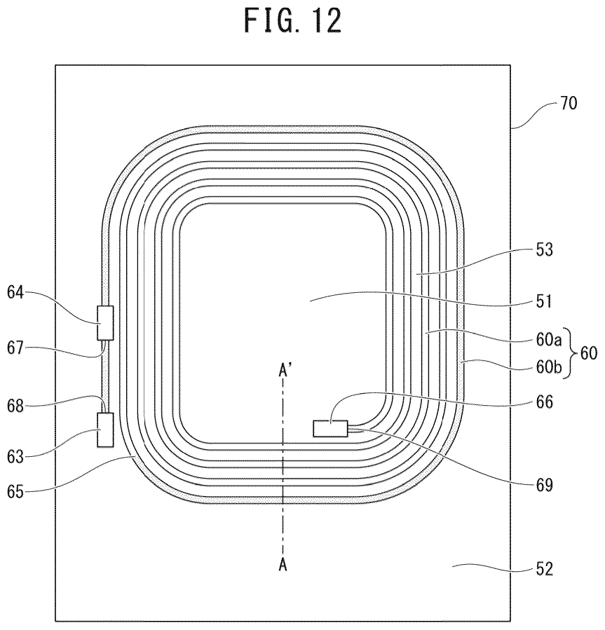

A semiconductor device according to a sixth embodiment is illustrated below with a case in which a resistive element is provided on a high voltage integrated circuit (HVIC), which is a high voltage device. As illustrated in FIG. 12, the semiconductor device according to the sixth embodiment is the HVIC including a high-potential-side region 51, a low-potential-side region 52 provided along the circumference of the high-potential-side region 51, and a voltage blocking structure 53 located between the high-potential-side region 51 and the low-potential-side region 52. A resistive element 60 is provided on the top surface side of the voltage blocking structure 53 so as to surround the high-potential-side region 51.

The high-potential-side region 51 has a substantially rectangular planar shape, for example. The high-potential-side region 51 is provided with a high-side circuit part (not illustrated) that is a circuit on the high potential side. The high-side circuit part is a CMOS circuit in which a lateral n-channel MOSFET and a lateral p-channel MOSFET are complementarily connected. The high-potential-side region 51 is electrically connected to a power-supply potential VB that is a maximum potential of the high-side circuit part.

The low-potential-side region 52 is provided with a low-side circuit part (not illustrated) that is a circuit on the low potential side. The low-potential-side region 52 is fixed to a ground potential GND that is a minimum potential, for example. The voltage blocking structure 53 is a diode referred to as a high voltage junction termination (HVJT). The voltage blocking structure 53 has a frame-like planar shape so as to surround the circumference of the high-potential-side region 51. The voltage blocking structure 53 electrically isolates the high-potential-side region 51 from the low-potential-side region 52.

The resistive element 60 is a sense resistor that outputs signals depending on a potential difference between the high-potential-side region 51 and the low-potential-side region 52. The resistive element 60 is a thin-film resistor such as a polysilicon resistor including polysilicon doped with impurities. The resistive element 60 has a spiral planar shape. The resistive element 60 includes a resistive part (a low-specific-resistive part) 60b including at least a region between an end part 68 of the resistive element 60 on the outer side (on the outer circumferential side) and a voltage-division point 67, and a resistive part (a high-specific-resistive part) 60a integrally connected to the resistive part 60b at a position closer to the end part on the inner side (on the inner circumferential side) than the resistive part 60b and having a lower impurity concentration and higher sheet resistance than the resistive part 60b. FIG. 12 schematically indicates the resistive part 60b with dot hatching for facilitation of distinction between the resistive part 60a and the resistive part 60b.

The end part 68 of the resistive element 60 on the outer side (on the outer circumferential side) is electrically connected to a ground contact part 63. The voltage-division point 67 of the resistive element 60 is electrically connected to a voltage-division-point contact part 64. An end part 69 of the resistive element 60 on the inner side (on the inner circumferential side) is electrically connected to a resistive element contact part 66. Detecting a voltage of the voltage-division point 67 of the resistive element 60 through the voltage-division-point contact part 64 can avoid wrong operations of the HVIC.

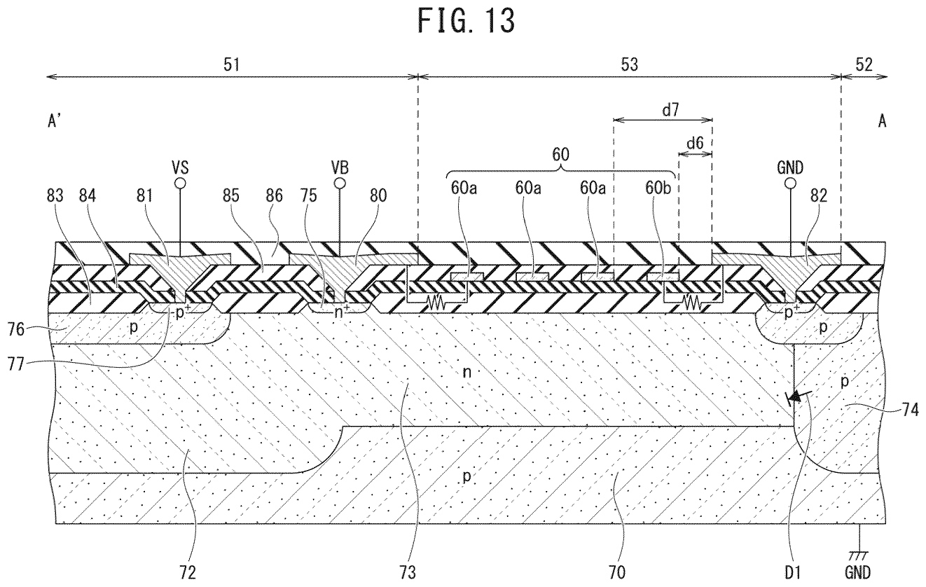

FIG. 13 is a cross-sectional view taken along line A-A′ in FIG. 12. As illustrated in FIG. 13, a semiconductor substrate 70 of p-type is fixed to the ground potential GND that is the minimum potential, for example. A semiconductor region (a well region) 72 of n-type, a semiconductor region (a well region) 73 of n-type, and a semiconductor region (a well region) 74 of p-type are selectively provided at the upper part of the semiconductor substrate 70. The well region 72 implements the high-potential-side region 51. The well region 72 is provided with the lateral p-channel MOSFET of the high-side circuit part, for example. The well region 72 is electrically connected to a VB electrode 80 via a semiconductor region (a contact region) 75 of n⁺-type provided at an upper part of the well region 72 and having a higher impurity concentration than the well region 72. The power-supply potential VB of the high-side circuit part is applied to the VB electrode 80.

A semiconductor region (a well region) 76 of p-type is provided at an upper part of the well region 72. The well region 76 is provided with the lateral n-channel MOSFET of the high-side circuit part, for example. The well region 76 is electrically connected to a VS electrode 81 via a semiconductor region (a well region) 77 of p⁺-type provided at an upper part of the well region 76 and having a higher impurity concentration than the well region 76. A reference potential VS of the high-side circuit part lower than the power-Supply potential VB is applied to the VS electrode 81.

The well region 73 is located at a position closer to the outer circumference than the well region 72 and is in contact with the well region 72. The well region 73 has a shallower depth than the well region 72, for example. The well region 74 is located at a position closer to the outer circumference than the well region 73 and is in contact with the well region 73. A semiconductor region of n-type (not illustrated) provided in the well region 74 implements the low-potential-side region 52. The well region 74 may implement a part of the semiconductor substrate 70. A semiconductor region (a well region) 78 of p-type is provided at an upper part of the well region 74. The well region 78 is electrically connected to a GND electrode 82 having a lower potential than the VS electrode 81 via a semiconductor region (a contact region) 79 of p⁺-type provided at an upper part of the well region 78 and having a higher impurity concentration than the well region 78. The minimum potential such as the ground potential GND lower than the power-supply potential VB and the reference potential VS is applied to the GND electrode 82.

The p-n junction between the p-type well region 74 and the n-type well region 73 provides a diode D1. The diode D1 implements the voltage blocking structure 53 and electrically isolates the high-potential-side region 51 from the low-potential-side region 52. The contact region 75 serves as a cathode region of the diode D1, and the contact region 79 serves as an anode region of the diode D1.

Insulating films 83 to 85 are sequentially provided on the top surface side of the semiconductor substrate 70. The VB electrode 80, the VS electrode 81, and the GND electrode 82 are provided on the top surface of the insulating film 85. The VB electrode 80, the VS electrode 81, and the GND electrode 82 each implement a metal wire which includes titanium (Ti) in barrier metal or a reflection-preventing film, for example. The VB electrode 80, the VS electrode 81, and the GND electrode 82 are covered with an insulating film 86.

The end part 69 of the resistive part 60a on the inner circumferential side of the resistive element 60 is electrically connected to the VB electrode 80 via the resistive element contact part 66 illustrated in FIG. 12. The end part 69 of the resistive part 60a on the inner circumferential side of the resistive element 60 may be electrically connected to the VS electrode 81 via the resistive element contact part 66 illustrated in FIG. 12. The end part 68 of the resistive part 60b on outer circumferential side of the resistive element 60 is electrically connected to the GND electrode 82 via the ground contact part 63 illustrated in FIG. 12. A distance d6 between the outer circumference of the resistive part 60b of the resistive element 60 and the GND electrode 82 is four micrometers or smaller, for example. A distance d7 between the outer circumference of the resistive part 60a of the resistive element 60 and the GND electrode 82 is greater than four micrometers, for example.

The semiconductor device according to the sixth embodiment has the configuration in which the part of the resistive element 60 on the outer circumferential side serves as the resistive part 60b with the relatively high impurity concentration, as in the case of the semiconductor device according to the first embodiment, regardless of whether the resistive element 60 is provided on the high voltage device such as a HVIC. This configuration can suppress or reduce the variation in the resistance value of the voltage-division point 67.

### Other Embodiments

As described above, the invention has been described according to the first to sixth embodiments, but it should not be understood that the description and drawings implementing a portion of this disclosure limit the invention. Various alternative embodiments of the present disclosure, examples, and operational techniques will be apparent to those skilled in the art from this disclosure.

While the respective semiconductor devices according to the first to sixth embodiments have been illustrated above with the case of including the resistive element 20, 40, or 60 for voltage sensing on the boot-up element such as the JFET 30 or the high voltage device such as the HVIC, the respective semiconductor devices may include the resistive element provided on any other device, for example, an insulated-gate field-effect transistor such as a MOSFET. In addition, the respective semiconductor devices according to the first to sixth embodiments have been illustrated above with the case of including the resistive element 20, 40, or 60 for voltage sensing, but may include any other resistive element, instead of the resistive element for voltage sensing.

While the respective semiconductor devices according to the first to sixth embodiments have been illustrated above with the case in which the end part of the resistive element 20, 40, or 60 on the outer side (on the outer circumferential side) is connected to the low-potential side and the end part of the resistive element 20 on the inner side (on the inner circumferential side) is connected to the high-potential side, the end part of the resistive element 20 on the outer side (on the outer circumferential side) may be connected to the high-potential side and the end part of the resistive element 20 on the inner side (on the inner circumferential side) may be connected to the low-potential side. In such a case, the part of the resistive element 20 on the inner side (on the inner circumferential side) that is the low-potential side may serve as a resistive part with a relatively high impurity concentration.

The respective configurations disclosed in the first to sixth embodiments can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising:
a semiconductor substrate;
a first semiconductor region provided in the semiconductor substrate;
a second semiconductor region provided in the semiconductor substrate;
a first electrode electrically connected to the first semiconductor region;
a second electrode electrically connected to the second semiconductor region;
an insulating film provided on a top surface side of the semiconductor substrate; and
a resistive element provided on a top surfaces side of the insulating film, having a structure in which one end is electrically connected to the first electrode and another end is connected to the second electrode, and including a voltage-division point toward the other end,
wherein the resistive element includes
a first resistive part including at least a region from the other end to the voltage-division point, and
a second resistive part integrally connected to the first resistive part at a position closer to the one end than the first resistive part and having a lower impurity concentration than the first resistive part.

2. The semiconductor device of claim 1, wherein the resistive element is a polysilicon resistor.

3. The semiconductor device of claim 1, wherein the resistive element has a spiral or meandering planar shape.

4. The semiconductor device of claim 1, wherein an outline of the resistive element has a circular, oval, or racetrack-like planar shape.

5. The semiconductor device of claim 1, wherein:
the first resistive part is located on an outer side; and
the second resistive part is located on an inner side.

6. The semiconductor device of claim 5, wherein:
a metal wire is provided to be opposed to an outer side of the first resistive part; and
a distance between the first resistive part and the metal wire is four micrometers or smaller.

7. The semiconductor device of claim 5, wherein a metal wire is provided over the first resistive part.

8. The semiconductor device of claim 1, wherein the second resistive part includes a region from a boundary with the first resistive part to the one end.

9. The semiconductor device of claim 1, wherein the resistive element further includes a third resistive part including the one end, integrally connected to the second resistive part at a position closer to the one end than the second resistive part, and having a higher impurity concentration than the second resistive part.

10. The semiconductor device of claim 1, further comprising a boot-up element including the first semiconductor region and the second semiconductor region.

11. The semiconductor device of claim 1, further comprising a high voltage integrated circuit including the first semiconductor region and the second semiconductor region.
